(19) United States
(12) Patent Application Publication
(10) Pub. No.: US 2005/0277065 A1
(43) Pub. Date: Dec. 15, 2005

(54) Method of manufacturing a semiconductor device

(76) Inventors: Norio Hasegawa, Hinode (JP); Katsuya Hayano, Hachioji (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/147,222

(22) Filed: Jun. 8, 2005

(30) Foreign Application Priority Data
Jun. 10, 2004 (JP) 2004-172905

(51) Int. Cl. G03F 7/00

(52) U.S. Cl. 430/312; 430/396

(57) ABSTRACT

By using a high-accuracy mask capable of being manufactured through a simplified step, a semiconductor device manufacturing method of forming a desired pattern over a wafer is provided. A relatively narrow groove pattern and a groove pattern wider than the narrow groove pattern are formed, and a shade film made of, for example, a resist film is formed in the relatively wide groove pattern. As a concrete method of manufacturing a mask, after applying a resist film onto the quartz glass substrate, exposure and developing processings are performed, whereby the resist film is patterned. The patterned resist film is used as a mask to form the groove patterns in the quartz glass substrate (dry etching). Subsequently, after removing the patterned resist film, a new resist film is applied. Then, patterning is performed to form the shade film only in the groove pattern.

### CROSS-REFERENCE TO RELATED APPLICATION

The present application claims priority from Japanese patent application No. JP 2004-172905 filed on Jun. 10, 2004, the content of which is hereby incorporated by reference into this application.

### BACKGROUND OF THE INVENTION

The present invention relates to a technique for manufacturing a semiconductor device and more specifically to a technique effectively applied to a photolithography technique for transferring a predetermined pattern to a semiconductor wafer (hereinafter abbreviated as “wafer”) by using a photo mask (hereinafter abbreviated as “mask”) in a manufacturing process of the semiconductor device.

In the manufacturing process of the semiconductor device, as a method for forming a fine pattern on the wafer, the photolithography technique has been employed. In this photolithography technique, a so-called optical projection exposure technique, in which a pattern formed on the mask is repeatedly transferred onto the wafer via a reduction projection optical system, has become the mainstream thereof.

A resolution R on the wafer in the optical projection exposure technique is generally expressed by R=k×λ/NA. Herein, “k” is a constant depending upon resist materials and processes, “i” is a wavelength of exposure light, and “NA” is the number of apertures of a projection exposure lens. As known from a relational expression of the resolution R, it is understood that a projection exposure technique for using a light source with a shorter wavelength is required as the fine pattern formed on the wafer is made fine. For example, by a projection aligner using an i ray of a mercury lamp (λ=365 nm), KrF excimer laser (λ=248 nm), or ArF excimer laser (λ=193 nm) as an illuminating light source, a semiconductor device is manufactured. In order to realize a further finer-pattern, an illuminating light source with a further shorter wavelength is required, so that adoption of, for example, an F₂ excimer laser (λ=157 nm) is under examinations.

Meanwhile, as a mask used in the projection exposure technique, there is a structure of forming, as a shade film, a shade pattern made of a chrome film etc. on a quartz glass substrate (blank) transparent to an illumination light (exposure light). However, as the pattern to be transferred is made fine, masks including phase information of a phase shift mask and a half tone mask, etc. are widely used. Utilization of the masks including such phase information is supposed to increase in future.

In the phase shift mask, a processing for giving a phase difference to light permeating the adjacent patterns is carried out on the mask. A method used at present as the mainstream thereof is one in which: a pattern made of a chrome film is formed; thereafter the quartz glass substrate, on which a pattern area in which the chrome film is not formed is exposed, is scraped so that a phase of a transmitted light can be reversed; and adjustment is made so that the phase of the light permeating the adjacent transparent patterns can be reversed.

Herein, as a technique using the phase shift mask, Japan Patent Laid-open No. 11-072902 discloses a technique in which: a plurality of grooves with different depths are formed in a shifter disposing area of the quartz substrate; attenuated phase shifters made of the same semi-transparent materials are embedded in these grooves; and thereby an optical proximity effect is compensated with high accuracy to improve the resolution of the pattern.

Further, Japan Patent Laid-open No. 2000-010256 discloses a technique as described below. That is, large and small concaves (grooves) are formed on a transparent substrate, and a semi-transparent film is formed in these concaves. Then, the film thickness of the semi-transparent film is changed so that the light radiated to the small concave and an edge of the large concave can be permeated and the light radiated to a center of the large concave cannot be permeated. Thereby, the desired pattern is transferred onto a resist film formed on the wafer.

By the way, in recent years, a shade film made of a chrome film etc. is used in forming a relatively large-size pattern. However, the shade film made of a chrome film etc. is not used in forming a fine pattern and a method of forming the pattern using a transparent phase shifter has attracted attention. Since not using a chrome film for a relatively fine pattern, the method is called a Cr-less Phase-shift Lithography (CPL) (For example, see W. Conley, et. Al, “Application of CPL reticle technology for the 65- and 50-nm node” Proc. SPIE Vol. 5040, pp. 392 (2003)).

### SUMMARY OF THE INVENTION

In the abovementioned CPL technology, the fine patter obtained by using the transparent phase shifter functions as a shade portion by a phase reverse effect at the edge of the pattern. However, if the transparent phase shifter is used also to the large-size pattern, the edge of the pattern becomes a shade portion. However, the transmitted light, whose phase is reversed, is not canceled at the center, so that the center does not function as a shade portion. Accordingly, it becomes difficult to form the desired pattern and a structure of forming the shade film made of a chrome file etc. becomes necessary in a large pattern portion in side.

Hereinafter, a method of manufacturing this chromeless phase shift mask will be described. First, a quartz glass substrate in which a chrome film is formed on a main surface thereof is prepared. Then, a positive type first electron beam sensitive resist film is applied on the chrome film, and thereafter an electron bean is radiated to a forming area for groove pattern. Then, by performing a developing processing thereto, a pattern in which the area radiated by the electron beam becomes an opening portion is formed.

Next, the chrome film exposed on a bottom of the opening portion is removed by dry etching (a first dry etching step). Further, the exposed quartz glass substrate by dry-etching the chrome film is scraped to a predetermined depth, whereby the groove pattern is formed (a second dry etching step). Even when this groove pattern is formed, the dry etching is employed. Note that a scraping amount of groove pattern is set to such a depth that the phase reverse effect can be obtained.

Subsequently, after the patterned positive type first electron beam sensitive resist film is removed, new negative type second electron beam sensitive resist films are applied onto the patterned chrome film and the groove pattern. An electron beam is radiated onto an area for forming a relatively large-size pattern (thick pattern). Next, by performing a normal developing processing thereto, a large-size pattern is formed on the second electron beam sensitive resist film. An area of the large-size pattern occupying in the quartz glass substrate is extremely small, and the second electron beam sensitive resist film is largely removed, and the lower chrome film is exposed at a removed region.

Thereafter, the exposed chrome film is removed by the dry etching (a third dry etching step), whereby a large-size pattern made of a chrome film is formed. Then, by removing the patterned second electron beam sensitive resist film, the chrome-less phase shift mask, in which a fine groove pattern having a phase shift effect and a large-size pattern made of the chrome film coexist, may be formed.

In the abovementioned steps, the dry etching step is required three times, whereby a mask manufacturing process becomes complicated and there arises a problem of defects in the mask due to foreign matters occurring in the dry etching steps. Especially, in the abovementioned third etching step, it is necessary to etch most of the chrome film, so that there easily arsis a problem of occurrence of the defects in the mask caused due to the foreign matters.

Further, in the abovementioned steps, the fine pattern and the large-size pattern are formed by separate electron beam drawings. Therefore, there is a problem such that the relative displacement of the fine groove pattern and the large-size pattern easily occurs.

An object of the present invention is to provide a method of manufacturing a semiconductor device by forming a desired pattern on a wafer using a high-precision mask capable of being manufactured in a simplified process.

The above and other objects and new features will be apparent from the description of this specification and the accompanying drawings.

Outlines of representative ones of inventions disclosed by the present application will be briefly described as follows.

A method of manufacturing a semiconductor device according to the present invention comprises the step of exposing a predetermined pattern on a photosensitive film formed on a semiconductor substrate by using a photo mask, wherein the photo mask includes: (a) a plurality of groove patterns formed in a blank; and (b) shade films formed in some ones among the plurality of groove patterns.

Effects obtained from representative ones of inventions disclosed by the present application will be briefly described as follows.

The desired pattern can be formed on the wafer by using the mask capable of being manufactured in the simplified process.

### BRIEF DESCRIPTION OF THE DRAWINGS

FIG. 1 is a top view showing an example of a mask in a first embodiment according to the present invention.

FIG. 2 is a sectional view taken along the line A-A in FIG. 1.

FIG. 3 is a graph showing a light intensity distribution when a groove pattern has a width of 0.05 μm.

FIG. 4 is a view showing a resist film formed when the groove pattern has a width of 0.05 μm.

FIG. 5 is a graph showing the light intensity distribution when a groove pattern has a width of 0.2 μm.

FIG. 6 is a view showing a resist film formed when the groove pattern has a width of 0.2 μm.

FIG. 7 is a view showing a displacement between the groove pattern and a shade film.

FIG. 8 is a graph showing an influence given to a transfer dimension to a wafer by a displacement amount of the shade film.

FIG. 9 is a view showing a relation between the width of the groove pattern and that of the shade film.

FIG. 10 is a graph showing a fluctuation amount of the transfer dimension to the wafer when the width of the shade film is made smaller than that of the groove pattern.

FIG. 11 is a graph showing a relation between the width (converted value on wafer) of the groove pattern and that of a pattern to be transferred onto the wafer.

FIG. 12 is a graph showing a relation between a width (converted value on wafer) of a groove pattern in which the shade film is embedded and that of the pattern to be transferred onto the wafer.

FIG. 13 is a top view showing a manufacturing process for a mask in the first embodiment.

FIG. 14 is a sectional view taken along the line A-A in FIG. 13.

FIG. 15 is a top view showing a manufacturing process of a mask in the first embodiment.

FIG. 16 is a sectional view taken along line the A-A in FIG. 15.

FIG. 17 is a sectional view showing a manufacturing process for the mask subsequently to FIG. 16.

FIG. 18 is a top view showing the manufacturing process for a mask in the first embodiment.

FIG. 19 is a sectional view taken along the line A-A in FIG. 18.

FIG. 20 is a top view showing the manufacturing process for a mask in the first embodiment.

FIG. 21 is a sectional view taken along the line A-A in FIG. 20.

FIG. 22 is a view showing a projection aligner used in the first embodiment.

FIG. 23 is a drawing for explaining a scanning operation of the projection aligner used in the first embodiment.

FIG. 24 is a top view showing a logic element in a semiconductor device in the first embodiment.

FIG. 25 is a sectional view showing a manufacturing process for a semiconductor device in the first embodiment.

FIG. 26 is a sectional view showing the manufacturing process of a semiconductor device subsequently to FIG. 25.

FIG. 27 is a sectional view showing the manufacturing process of a semiconductor device subsequently to FIG. 26.

FIG. 28 is a sectional view showing the manufacturing process of a semiconductor device subsequently to FIG. 27.

FIG. 29 is a sectional view showing the manufacturing process of a semiconductor device subsequently to FIG. 28.

FIG. 30 is a sectional view showing the manufacturing process of a semiconductor device subsequently to FIG. 29.

FIG. 31 is a sectional view showing the manufacturing process of a semiconductor device subsequently to FIG. 30.

FIG. 32 is a sectional view showing the manufacturing process of a semiconductor device following FIG. 31.

FIG. 33 is a sectional view showing the manufacturing process of a semiconductor device subsequently to FIG. 32.

FIG. 34 is a top view of a gate electrode forming pattern.

FIG. 35 is a top view showing a pattern of a mask for gate electrode forming mask.

FIG. 36 is a top view showing a manufacturing process for a gate electrode forming mask.

FIG. 37 is a sectional view showing the manufacturing process of a semiconductor device subsequently to FIG. 33.

FIG. 38 is a sectional view showing the manufacturing process of a semiconductor device subsequently to FIG. 37.

FIG. 39 is a sectional view showing the manufacturing process of a semiconductor device subsequently to FIG. 38.

FIG. 40 is a sectional view showing the manufacturing process of a semiconductor device subsequently to FIG. 39.

FIG. 41 is a sectional view showing the manufacturing process of a semiconductor device subsequently to FIG. 40.

FIG. 42 is a sectional view showing the manufacturing process of a semiconductor device subsequently to FIG. 41.

FIG. 43 is a sectional view showing the mask used in the first embodiment.

FIG. 44 is a sectional view showing a mask in a second embodiment.

### DESCRIPTION OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, a supplementary explanation or the like thereof.

Also, in the embodiments described below, when referring to the number of elements (including number of pieces, values, amounts, ranges, or the like), the number of elements is not limited to a specific number unless otherwise stated, or except the case where the number is apparently limited to a specific number in principle, or the like. The number larger or smaller than the specified number is also applicable.

Further, in the embodiments described below, it goes without saying that the components (including element steps or the like) are not always essential unless otherwise stated, or except the case where the components are apparently essential in principle, or the like.

Similarly, in the embodiments described below, when the shape of the components and the like, or the positional relation and the like thereof, or the like are mentioned, the substantially approximate and similar shapes and the like are included therein unless otherwise stated, or except the case where it can be conceived that they are apparently excluded in principle, or the like. This condition is also applicable to the numerical value and the range described above.

Also, components having the same functions are denoted by the same reference symbols throughout the drawings for describing the embodiments, and the repetitive description thereof will be omitted.

Further, the drawings may be hatched in some cases in order to be understood easily even if not sectional views.

Hereinafter, embodiments of the present invention will be detailed with reference to the drawings.

### First Embodiment

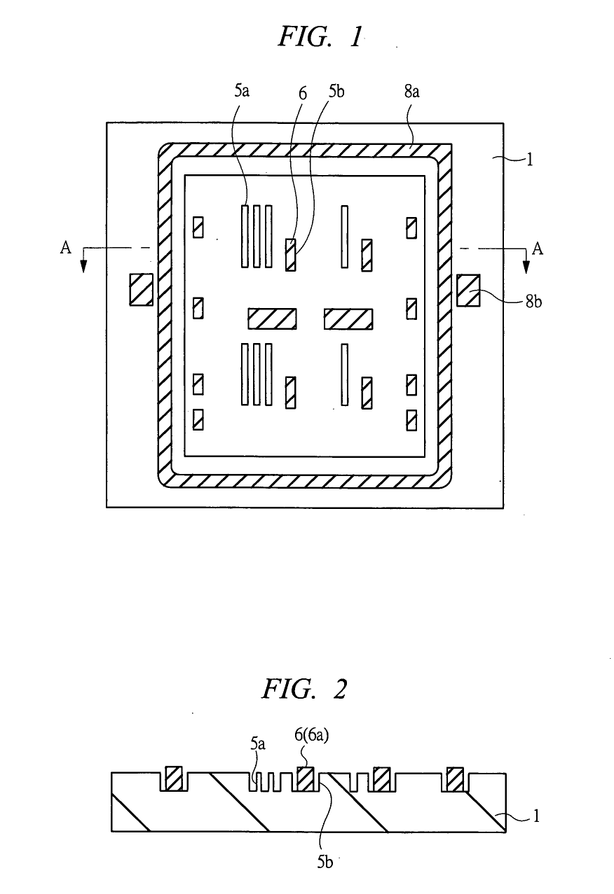

FIG. 1 is a top view showing an example of a mask in a first embodiment, and FIG. 2 is a sectional view taken along the line A-A in FIG. 1. As shown in FIG. 1, in a mask in the first embodiment, groove patterns (first groove patterns) 5a and groove patterns (second groove patterns) 5b are formed in a quartz glass substrate 1 (blank), wherein a shade film 6 is formed in each groove pattern 5b.

As shown in FIG. 2, the groove pattern 5a is formed of a relatively narrow groove, and the groove pattern 5b is formed of a relatively wide groove. Further, only in the relatively wide groove pattern 5b, the shade film 6 is formed. The relatively narrow groove pattern 5a is one for transferring a fine pattern onto a wafer, and the relatively wide groove pattern 5b is one for transferring a large-size pattern on the wafer.

These groove patterns 5a and 5b serve as shade areas in the mask. Namely, because the groove patterns 5a and 5b are formed in the quartz glass substrate 1, exposure light permeating an area having no groove in the quartz glass substrate 1 and exposure light permeating an interior of the groove are canceled mutually, thereby becoming-shade areas. Namely, each depth of the groove patterns 5a and 5b is determined so that optical path length of the exposure light permeating the area having no groove and that of the exposure light permeating the groove are displaced 180 degrees in phase. Therefore, the exposure light permeating the area having no groove and the exposure light permeating the groove are canceled mutually.

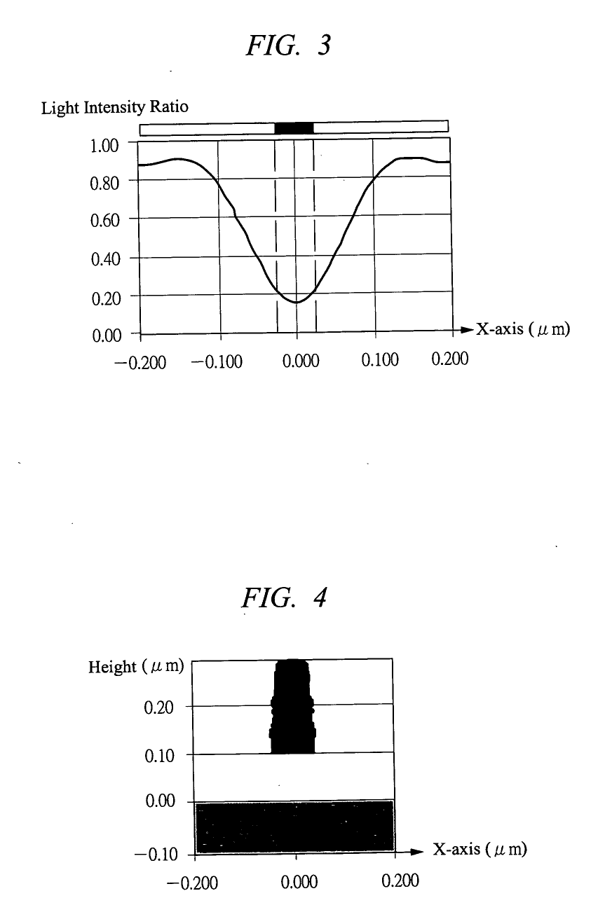

Herein, a relation between a width of the groove pattern and a light intensity distribution obtained by the groove pattern and a relation between the width of the groove pattern and a pattern of a resist film to be formed are shown in FIGS. 3 to 6. FIG. 3 shows the light intensity distribution when the width of the groove pattern is 0.05 μm. In FIG. 3, a horizontal axis shows coordinates in an X-axis direction, and a vertical axis shows a light intensity ratio (absolute value) of transmitted light to radiated light. As seen from FIG. 3, it is known that a black area is the groove pattern and the width of this groove pattern is 0.05 μm. At this time, the light intensity ratio under the groove pattern becomes approximately 0.2 and its value is smaller than those of the light intensity ratio of portions other than the groove pattern. Therefore, it is understood that when the width of the groove pattern is 0.05 μm, a shade characteristic becomes preferable by a decline of the light intensity ratio under the groove pattern.

FIG. 4 shows a pattern of a resist film formed when the width of the groove pattern is 0.05 μm. In FIG. 4, a horizontal axis shows coordinates in the X-axis direction, and a vertical axis shows the height of the resist film.

As seen from FIG. 4, it is known that a preferable pattern with a width of approximately 0.05 μm and a height of approximately 0.2 μm is formed in the resist film. This is caused by the fact that the shade characteristic of the groove pattern used in the mask is preferable. Namely, when the width of the groove pattern is as fine as 0.05 μm, the shade characteristic by the groove pattern is preferable and therefore the patterning of the resist film also becomes preferable.

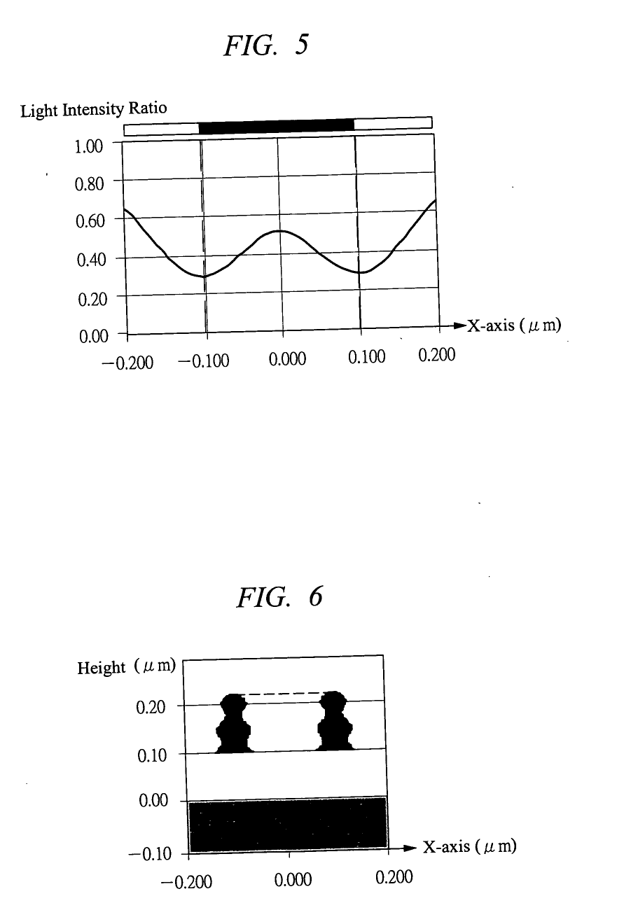

In contrast, FIG. 5 shows a light intensity distribution when the width of the groove pattern is 0.2 μm. In FIG. 5, a horizontal axis shows coordinates in the X-axis direction and the vertical axis shows the light intensity ratios (absolute values). As seen from FIG. 5, it is known that although declines of the light intensity ratio by the phase reverse effect occur at edges of the groove, a transmitted light intensity becomes high at a center of the groove pattern. More specifically, although the light intensity is approximately 0.3 at the edges of the groove pattern, the light intensity ratio goes up to approximately 0.5 at the center of the groove pattern.

As shown above, when the width of the groove pattern is as relatively large as 0.2 μm, the exposure light permeating the area having no groove and the exposure light permeating the interior of the groove are canceled mutually at the edges of the groove pattern. However, the light intensity of the exposure light permeating the area having no groove becomes small at the center of the groove pattern while that of the exposure light permeating the interior of the groove becomes large at the center of the groove pattern. As a result, the light intensity ratio of the exposed light remaining without being canceled becomes large, and the shade characteristic of the groove pattern deteriorates.

FIG. 6 shows a pattern of a resist film to be formed when the width of the groove pattern is 0.2 μm. In FIG. 6, a horizontal axis shows coordinates in the X-axis direction, and a vertical axis shows height of the resist film. As seen from FIG. 6, it is known that the resist film is lost at the center thereof and thereby the preferable pattern is not formed. Namely, by using as a mask the groove pattern with a width of 0.2 μm, it is intended to form the resist film whose pattern cross section is roughly rectangular. However, because the shade characteristic at the center of the groove pattern is bad, the light intensity of transmitted light becomes large. Accordingly, it is understood that the resist film at the center of the resist pattern is lost by the developing processing, whereby two patterns separated at the center are formed.

Thus, it is understood that when the permeating exposure light is shielded by the groove pattern, there is not any problem in forming a fine pattern, but when a certain level of large-size pattern is formed, the shade characteristic at the center deteriorates and the pattern of the resist film cannot be formed normally.

Accordingly, in a conventional technique, a groove pattern capable of obtaining a phase shift effect is used in forming a fine pattern and a shade pattern is formed by using a chrome film without forming the groove pattern in a large-size pattern. However, in such a mask, as mentioned previously, the dry etching must be carried out three times in the manufacturing process, so that the manufacturing process becomes complicated and defects in the mask occur easily since the foreign matters by the dry etching are generated. Further, the groove pattern and the shade pattern made of a chrome film are formed by the separate electron beam drawings, so that the relative displacement of the groove pattern and the large-size pattern occurs easily.

Therefore, as shown in FIGS. 1 and 2, in the first embodiment, in order to form both of a fine pattern and a large-size pattern, the groove patterns 5a and 5b corresponding respectively to the above-mentioned patterns are formed in the mask and concurrently the shade film 6 made of a resist film 6a is formed in the wide groove pattern 5b. Namely, the wide groove pattern 5b is formed for forming a large-size pattern and, to ensure the shade characteristic at the center of the groove pattern 5b, the shade film 6 is formed in the groove pattern 5b.

Thus, by using the groove pattern 5a capable of obtaining the phase shift effect in the entire groove when the fine pattern is formed, the preferable fine pattern can be formed. Concurrently, by using a pattern in which the shade film 6 is embedded in the groove pattern 5b when the large-size pattern is formed, the preferable pattern can be formed.

Further, in the groove pattern 5b in which the shade film 6 is embedded, because the edges thereof are determined by the groove pattern 5b, it is possible to reduce the influence by displacement of the embedded shade film 6 and the influence by size of the shade film 6.

The shade film 6 must have a characteristic of shielding the exposure light and, for example, an organic photosensitive resin film may be used. As the organic photosensitive resin film, there is, for example, a resist film exposed to the electron beam. As the shade characteristic of the shade film 6 to the exposure light, for example, a transmittance of the exposure light to the shade film is required to be 0.1% or below.

As explained above, the mask in the first embodiment has a structure comprising: the groove pattern 5a scraped in the quartz glass substrate 1 to form the fine pattern; the wide groove pattern 5b scrapped in the quartz glass substrate 1 to form the large-size pattern; and the shade film 6 with which the groove pattern 5b is filled. Further, in the mask, a shade pattern 8a around an element pattern forming area, mark patterns 8b for alignment of the aligner and mask, and an accessory pattern necessary for exposure are formed, wherein these patterns also are formed of groove patterns in which the shade films are embedded.

Note that, in a pattern other than the patterns for forming elements, when a shade characteristic of light different from the exposure light is required or when transmittance of detected light is high and the pattern is difficult to detect, a light absorbing agent etc. having the shade characteristic with respect to the light may be added to the shade film or a shade characteristic must be obtained by having such a structure that the pattern is formed into a shape of split with a resolution limit or less of the light. Namely, the shade film to be embedded in the groove pattern is required to have the shade characteristic to the exposure light. However, in patterns other than the element forming patterns such as the mark patterns for alignment with the aligner and the mask, etc., light different from the exposure light in kind may be employed. Therefore, in the patterns other than the element forming patterns, it is necessary to obtain the sufficient shade characteristic to the light different from the exposure light.

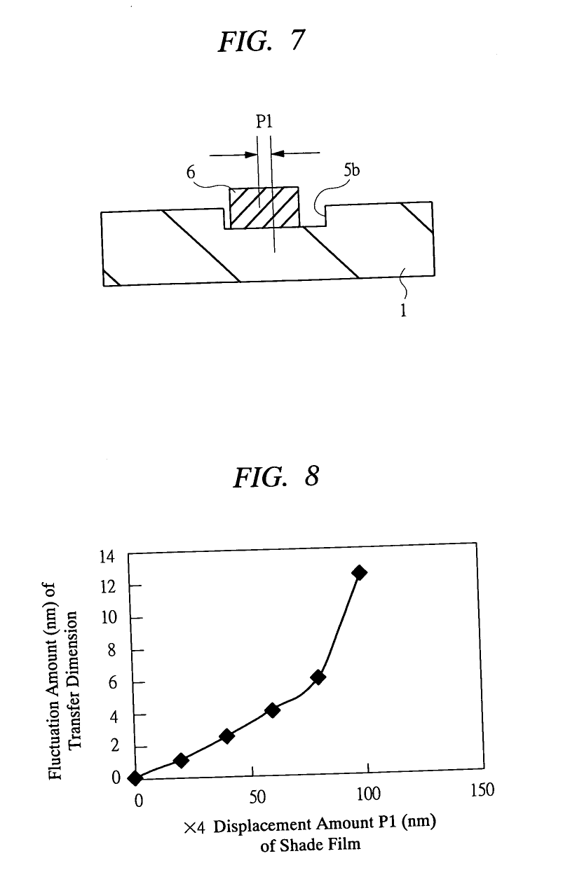

Next, a description will be made of an influence exerted on the transfer dimensions to the wafer by the displacement between the groove pattern 5b formed in the mask and the shade film 6 formed in this groove pattern 5b. FIG. 7 is a view showing the case where there is the relative displacement between the groove pattern 5b formed in the quartz glass substrate 1 and the shade film 6 formed in this groove pattern 5b. In FIG. 7, an amount of relative displacement between the groove pattern 5b and the shade film 6 is defined as “P1”.

FIG. 8 is a view showing that when there is the relative displacement between the groove pattern 5b and the shade film 6 shown in FIG. 7, the displacement amount P1 exerts the influence on the transfer dimensions to the wafer. In FIG. 8, a horizontal axis shows the displacement amount P1 (nm) of the shade film 6 in the case where the aligner used in transferring the pattern to the wafer has a reduced magnification of ¼, and a vertical axis shows a fluctuation amount (nm) of a pattern dimension to be transferred to the wafer. As seen from FIG. 8, as the displacement amount P1 of the shade film 6 increases, the fluctuation amount of the pattern dimension transferred to the wafer increases and, especially, when the displacement amount P1 of the shade film 6 exceeds approximately 80 nm, the fluctuation amount of the pattern dimension transferred to the wafer increases rapidly too.

Herein, the shade film 6 is formed through a patterning processing by the electron beam writer, and positioning precision of the normally used electron beam aligner is approximately 30 nm. Therefore, the displacement amount P1 of the shade film 6 becomes approximately 30 nm in consideration of the positioning precision of the electron beam aligner. At this time, it is understood that the fluctuation amount of the pattern dimension transferred to the wafer is approximately 2 nm from FIG. 8 and the influence exerted on the pattern dimension transferred to the wafer is extremely small. Namely, it is understood that when the displacement amount P1 of the shade film 6 is a level of the positioning precision of the electron beam aligner, there is not a significant problem.

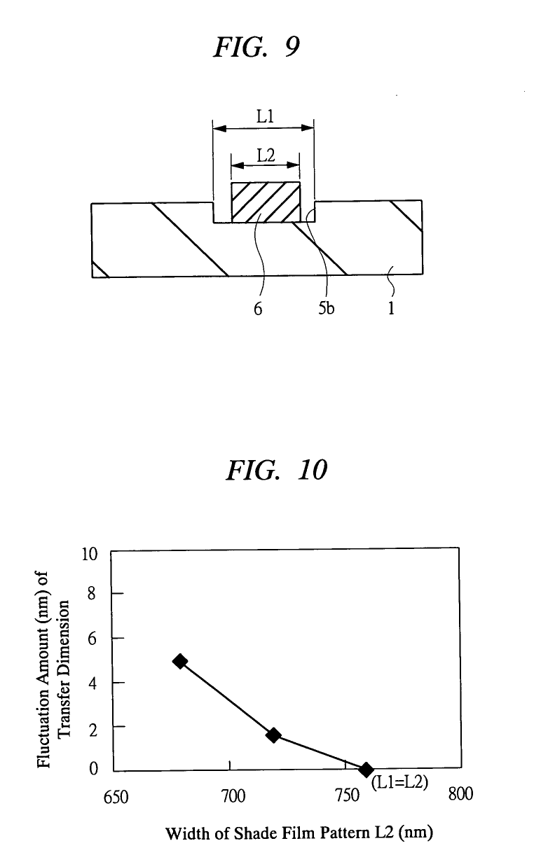

Next, a description will be made of an influence exerted on the transfer dimension to the wafer by the fluctuation of the pattern dimension of the shade film 6 formed in the groove pattern 5b. FIG. 9 shows width L1 of the groove pattern 5b and width L2 of the shade film 6 when the groove pattern 5b is formed on the quartz glass substrate 1 and the shade film 6 is formed in this groove pattern 5b. FIG. 10 is a graph showing the fluctuation amount of the transfer dimension to the wafer when the width L2 of the shade film 6 is made smaller than the width L1 of the groove pattern by setting, to an initial value, the case where the width L2 of the shade film 6 is equal to the width L1 of the groove pattern 5b. From the graph shown in FIG. 10, in the case of using the mask in the first embodiment in the aligner, a deterioration phenomenon of the shade film 6 made of, for example, a resist film may be evaluated. Namely, the shade film made of a resist film is an organic matter and, under irradiation of a strong ultraviolet ray at a time of using the mask, the shade film 6 reacts with oxygen in air and is discomposed. Therefore, the width L2 of the shade film 6 made of a resist film decreases. Accordingly, by checking the fluctuation amount of the transfer dimension to the wafer when the width L2 of the shade film 6 decreases from the initial dimension, the influence of the deterioration of the shade film 6 can be evaluated.

As shown in FIG. 10, the case where the width L2 of the shade film 6 is the same as the width L1 of the groove pattern 5b, i.e., is 760 nm is set to a standard of the fluctuation amount of the transfer dimension (fluctuation amount 0). At this time, even if the width L2 of the shade film 6 decreases from 760 nm by approximately 40 nm, i.e., becomes approximately 720 nm, the fluctuation amount of the transfer dimension to the wafer is approximately 1.5 nm. Accordingly, it is understood that even if the width L2 decreases due to the deterioration of the shade film 6, the influence executed on the transfer dimension is at a level without trouble.

Next, in the mask in the first embodiment, the groove pattern 5a is used for forming the fine pattern and the groove pattern 5b in which the shade film 6 is embedded in forming the large-size pattern is used. However, a description will be made of a border between the case of forming a transfer pattern by using the groove pattern 5a and the case of forming a transfer pattern by using the groove pattern 5b in which the shade film 6 is embedded. Namely, an evaluation is made of: using the groove pattern 5a, by which the phase shift effect is obtained, at which level a dimension of the transfer pattern is; or using the groove pattern 5b, in which the shade film 6 is embedded, at or beyond which level a dimension of the transfer pattern is.

The conditions used for transfer are shown below. First, as exposure light, an ArF excimer laser with a wavelength of 193 nm is used; and a lens of an optical system has an aperture of 0.7; an illumination shape is like a ring band; a σ ratio is 0.85/0.57; and a resist film to be transferred has a thickness of 0.2 μm.

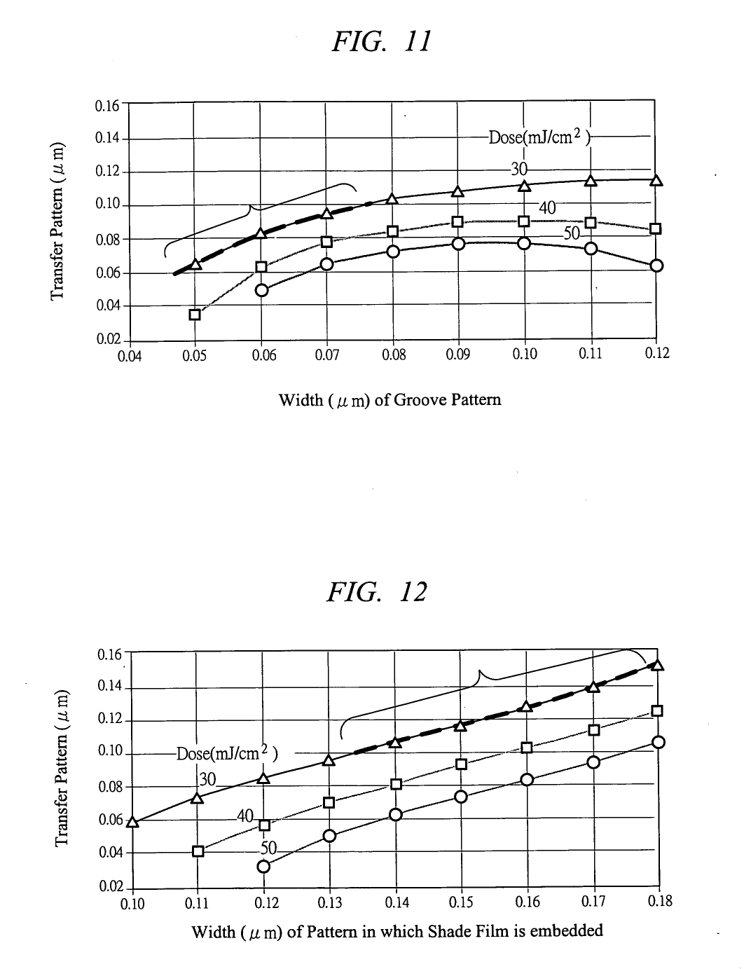

FIG. 11 is a graph showing a relation between the width (converted value on wafer) of the groove pattern 5a and that of the pattern to be transferred onto the wafer. In FIG. 11, triangle marks show the case where an exposure dose is 30 (mJ/cm²), square marks show the case where the exposure dose is 40 (mJ/cm²), and circle marks shows the case where the exposure dose is 50 (mJ/cm²).

As seen from FIG. 11, in the case where the exposure dose is 50 (mJ/cm²), as the width of the groove pattern 5a is increased from approximately 0.06 (μm) to approximately 0.09 (μm), the dimension of the transfer pattern accordingly increases from approximately 0.05 (μm) to approximately 0.08 (μm). Therefore, until the width of the groove pattern 5a reaches 0.09 (μm) in the converted value on wafer, the transfer patter can be normally formed. However, if the width of the groove pattern 5a is increased beyond 0.09 (μm), the width of the transfer pattern does not increase but decrease. For this reason, when the width of the groove pattern 5a is 0.09 (μm) or more, it is understood that the transfer pattern cannot be normally formed.

In the same manner, also in the case where the exposure dose is 40 (mJ/cm²), until the width of the groove pattern 5a reaches approximately 0.09 (μm), the transfer pattern is formed normally. However, when the width of the groove pattern 5a exceeds approximately 0.09 (μm), the width of the transfer pattern does not increase but decreases. Therefore, it is understood that the transfer pattern cannot be formed normally.

In the case where the exposure dose is 30 (mJ/cm²), as the width of the groove pattern 5a is increased from approximately 0.05 (μm) to approximately 0.075 (μm), the dimension of the transfer pattern accordingly increases from approximately 0.06 (μm) to approximately 0.10 (μm). Accordingly, until the width of the groove pattern 5a reaches 0.075 (μm) in the converted value on wafer, the transfer patter can be normally formed. However, as the width of the groove pattern 5a is increased beyond 0.075 (μm), the width of the transfer pattern does not decrease and the width of the transfer pattern increases only slightly with respect to an increase in the width of the groove pattern 5a. For this reason, it is understood that when the exposure dose is 30 (mJ/cm²), the width of the pattern capable of being transferred normally by the groove pattern 5a is 0.10 (μm) or below.

Next, FIG. 12 is a graph showing a relation between the width (converted value on wafer) of the groove pattern 5a in which the shade film 6 is embedded and the width of the pattern to be transferred onto the wafer. As seen from FIG. 12, in any of the cases where the exposure doses are 30 (mJ/cm²), 40 (mJ/cm²), and 50 (mJ/cm²), as the width of the groove pattern 5a in which the shade film 6 is embedded increases, the width of the transferred pattern increases too. Therefore, it is understood that the transfer pattern can be formed normally by using the groove pattern 5a in which the shade film 6 is embedded.

From the above descriptions, for example, in the case where the exposure dose is 30 (mJ/cm²), when the transfer pattern is formed until its width reaches 0.1 (μm), the groove pattern 5a may be used as a mask, and when the transfer pattern with a width of 0.1 (μm) or more is formed, the groove pattern 5b in which the shade film 6 is embedded may be used as a mask.

Next, a method for manufacturing a mask in the first embodiment will be described with reference to the drawings.

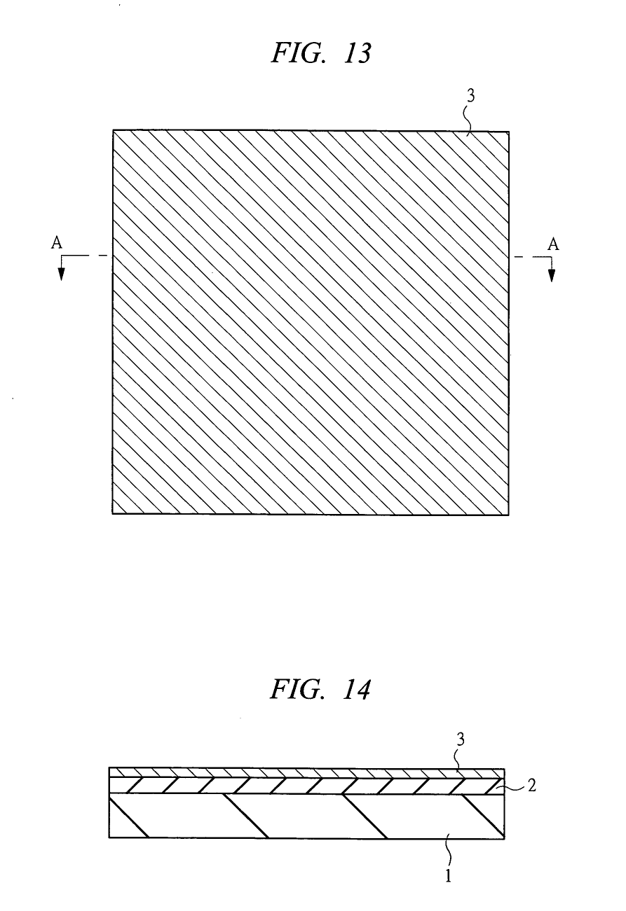

As shown in FIG. 13 and FIG. 14 showing a sectional view taken along the lien A-A in FIG. 13, first, a positive type, electron beam sensitive resist film (first resist film) 2 is applied onto the quartz glass substrate 1, and a conductive film (first conductive film) 3 is formed on the resist film 2. This conductive film 3 is formed for preventing charges by an electron beam at a time of make an electron beam drawing as described later.

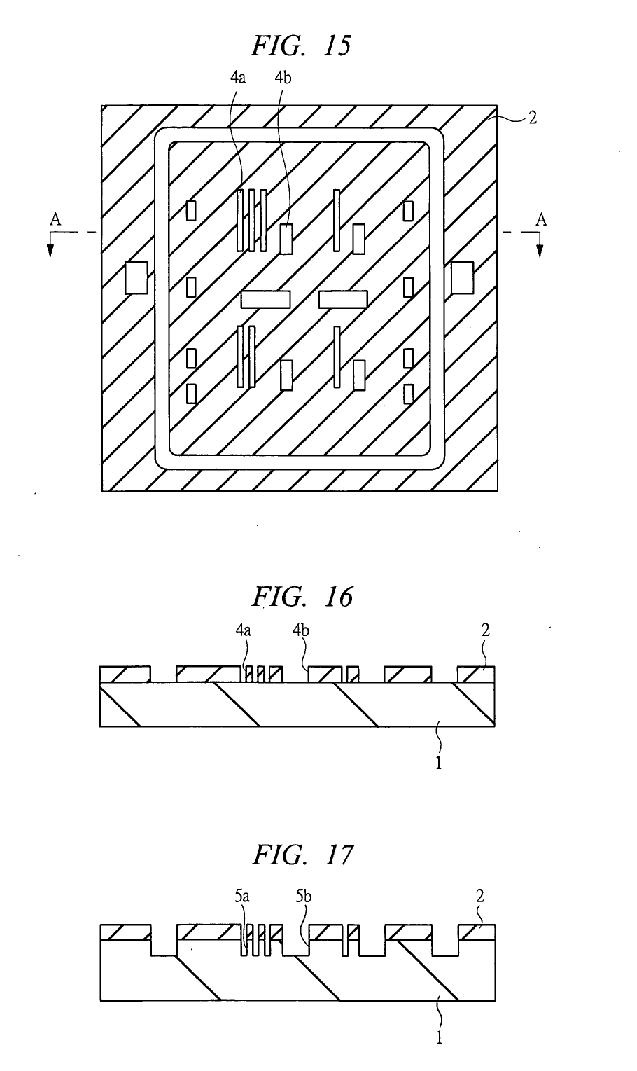

Subsequently, as shown in FIG. 15 and FIG. 16 showing a sectional view taken along the lien A-A in FIG. 15, after the electron beam is radiated on desired pattern portions 4a and 4b (electron beam drawing), a developing processing is carried out to form the resist film 2 in which the pattern portions 4a and 4b are opened. Note that the width of the pattern portion 4a is relatively narrow while that of the pattern portion 4b is relatively wide.

In this case, in performing the developing processing, the conductive film 3 formed on the resist film 2 is removed. Namely, the conductive film 3 made of, for example, a water-soluble organic film is removed by a developer. As the conductive film 3, for example, espacer (manufactured by Showa Denko KK), Aquasave (manufactured by Mitsubishi Rayon Co., Ltd.), or the like is employed.

Further, the conductive film 3 is electrically connected to the ground of the electron beam writer for radiating electron beams, whereby the resist film 2 is prevented from being charged at the time of radiating the electron beams onto the resist film 2. Therefore, it is possible to prevent drawbacks such as abnormality of each pattern shape and a displacement of patterns of the resist film 2.

Next, as shown in FIG. 17, by using as a mask the resist film 2 whose pattern portions 4a and 4b are opened, the exposed portion of the quartz glass substrate 1 is scraped to a predetermined depth to form the groove patterns 5a and 5b. These groove patterns 5a and 5b may be formed by using, for example, the dry etching. Each of the groove patterns 5a and 5b has such a depth as to be capable to obtaining the phase reverse effect. For example, in the case of using the ArF excimer laser with a wavelength of 193 nm as exposure light, each depth of the groove patterns 5a and 5b is, for example, 190 nm. Further, in the case of using the KrF excimer laser with a wavelength of 248 nm as exposure light, each depth of the groove patterns 5a and 5b is, for example, 245 nm.

Note that since the groove patterns 5a and 5b are formed respectively so as to correspond to the pattern portions 4a and 4b formed in the resist film 2, the width of the groove pattern 5a is relatively narrow and that of the groove pattern 5b is relatively wide.

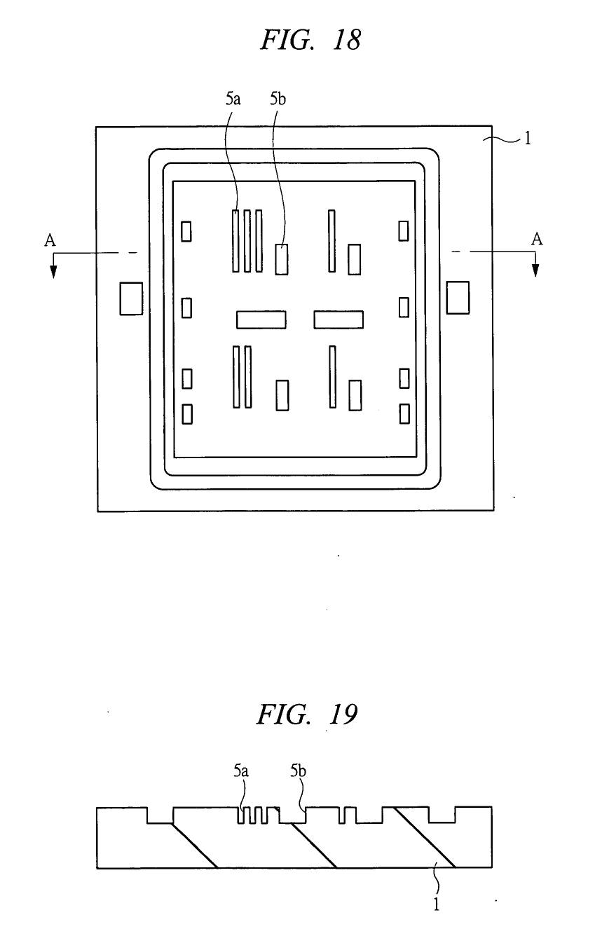

Subsequently, by removing the patterned resist film 2, as shown in FIGS. 18 and 19 showing a sectional view taken along the line A-A in FIG. 18, a phase shift mask in which the groove patterns 5a and 5b are formed in the quartz glass substrate 1 may be formed.

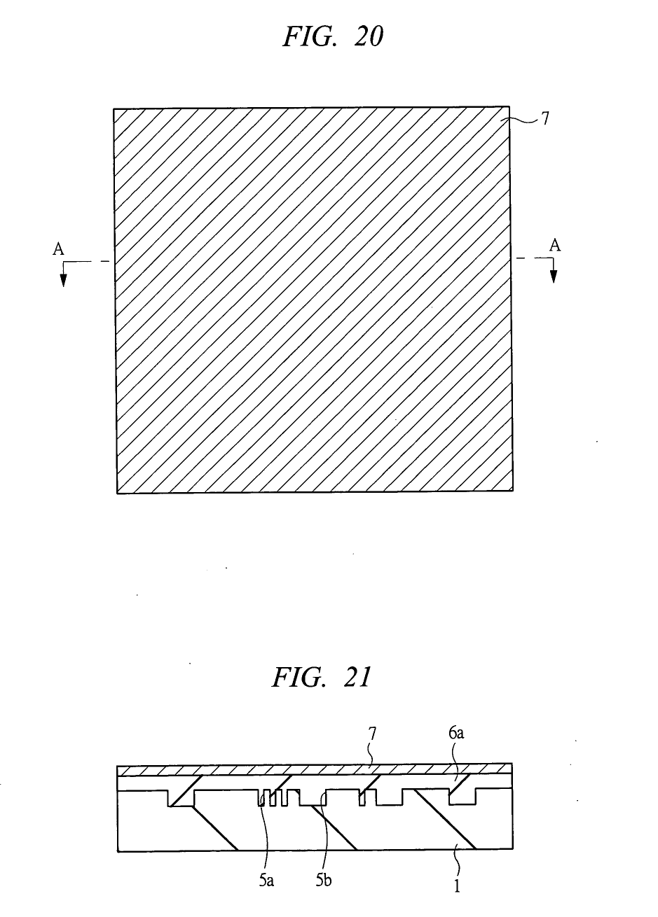

However, as the groove pattern 5b formed in this phase shift mask becomes wide, the shade characteristic thereof becomes insufficient and the normal transfer pattern cannot be formed. Therefore, in the first embodiment, by the step as shown below, the resist film (second resist film) 6a to be a shade film is formed in the groove pattern 5b. Namely, as shown in FIG. 20 and FIG. 21 showing a sectional view taken along the line A-A in FIG. 20, the resist 6a is formed on the quartz glass substrate 1 in which the groove patterns 5a and 5b are formed.

The resist film 6a is formed on the quartz glass substrate 1 by using, for example, a spin coat method etc. This resist film 6a is required to have a characteristic of absorbing the exposure light, such as a KrF excimer laser, ArF excimer laser, or F2 laser and concurrently to have a characteristic sensitive to electron beams. Namely, the resist film 6a is required to be formed in the groove pattern 5b and have a characteristic of shielding the exposure light when the mask is used. At the same time, the resist film 6a is required to have a characteristic sensitive to the exposure light since patterning of the resist film 6a is carried out by, for example, the electron beam in forming the mask.

More specifically, the resist film 6a has been formed of a novolac system resist film with a thickness of, for example, 200 nm. However, the present invention is not limited to this film. For example, the resist film 6a may contain a copolymer of α-methyl styrene and α-chloro acrylic acid, a novolac resin and quinone diazide, a novolac resin and poly methyl penten-1-sulfone, chloro methyl polystyrene, or the like as a main component or contain a naphthol phenyl resin and naphthol-novolac resin, a naphthol acrylate resin, or an antrasen added-novolac resin as a main component. Further, for example, a mixture of a phenol resin such as a polyvinyl phenol resin or a novolac resin and inhibiter and acid generator, a so-called chemical amplitude type resist film may be used.

The above materials of the above resist film 6 are ones for shielding a vacuum ultraviolet ray with a wavelength of 200 nm or below. However, the present invention is not limited to this. For example, in the case of shielding the KrF excimer laser with a wavelength of 248 nm, other materials for the resist film 6a may be employed, or a light absorbing agent or light shielding agent may be added to the resist film 6a.

Note that a material of the resist film 6a is not limited to the above materials and can be variously modified so long as it has a shade characteristic to a light source of the projection aligner and has a sensitive characteristic to a light source of a pattern writer used in the mask manufacturing process, for example, to an electron beam. Further, it is not limited to the above film with a thickness of 200 nm either.

Subsequently, after the resist film 6a is formed on the quartz glass substrate 1, a conductive film (second conductive film) 7 is formed on the resist film 6a. The conductive film 7 is formed for preventing charge by the electron beam at a time of making the electron beam drawing as described later, and is made of, for example, a water-soluble organic film etc. in the same manner as the abovementioned conductive film 3.

Next, by performing the developing processing after the electron beam is radiated onto a predetermined area of the resist film 6a, the shade film 6 (resist film 6a ) is left only in the relatively wide groove pattern 5b, as shown in FIG. 1 and FIG. 2 showing a sectional view taken along the line A-A in FIG. 1. By the developing processing carried out then, the conductive film 7 is removed.

Since the patterning of the resist film 6a is carried out so as to match a location of the groove pattern 5b, an engagement allowance is taken in the patterning of the resist film 6a. Accordingly, the width of the resist film 6a to be embedded in the groove pattern 5b is smaller than that of the groove pattern 5b.

Note that since a peripheral portion of the mask (outside of the element pattern forming area) becomes a contact portion to the projection aligner, the resist film 6a is removed therefrom and thereby occurrence of foreign matters caused by peeling and cracks etc. of the resist film 6a due to a mechanical impact is prevented.

Herein, by using, for example, a negative type resist film as the resist film 6a, a mask can be manufactured by a Quick Turn Around Time (Q-TAT). Namely, as mentioned previously, since the occurrence of the foreign matters is caused by leaving the resist film 6a outside the element pattern forming area, it is necessary to remove the resist film 6a located outside the element pattern forming area. At this time, if the resist film 6a is a positive type resist film, the area drawn by the electron beams is removed by the developing processing. Therefore, it is necessary to be drawn by the electron beam also with respect to most of the area located outside the element forming pattern area, so that it takes time. In contrast, if a negative type resist film is used as the resist film 6a, the area not drawn by the electron beam is removed by the developing processing. Accordingly, in the main surface of the mask, it is preferable to draw only a relatively small area (pattern forming area) by the electron beams. For this reason, the drawing area can be made small and the drawing time can be shortened.

Further, after performing a processing for leaving the resist film 6a only in the groove pattern 5b, a so-called hardening processing of the resist film may be carried out. The hardening processing can be performed by, for example, a processing for adding a heat treatment or a processing for strongly radiating an ultraviolet ray. By this hardening processing, it is possible to improve durability of the resist film 6a wit respect to exposure light irradiation during use of the mask.

Thus, the mask in the first embodiment, in which the relatively narrow groove pattern 5a and the relatively wide groove pattern 5b are formed and the shade film 6 made of the resist film 6a is formed only in the groove pattern 6b, can be formed.

According to the method of manufacturing the mask according to the first embodiment, since the dry etching step is employed only in a step of forming the groove patterns 5a and 5b in the quartz glass substrate 1, the number of dry etching steps is reduced in comparison with a conventional mask manufacturing method. Namely, in the case of forming the groove pattern and the shade pattern made of a chrome film similarly to the conventional mask, the dry etching step is required three times. However, the first embodiment can be obtained by using the dry etching step only once.

Accordingly, in the first embodiment, it is possible to simplify the mask manufacturing process and suppress defects in the mask, which are caused from the foreign matters occurring in the dry etching step. Further, since the mask manufacturing process can be simplified, it is possible to shorten a Turn Around Time (TAT) and further improve a yield thereof.

Further, in the conventional mask, since the groove pattern and the shade pattern made of a chrome film are formed by the separate electron beam drawings, a relative displacement occurs easily between the groove pattern and the shade pattern made of a chrome film. However, in the present embodiment, since the relatively narrow groove pattern 5a and the relatively wide groove pattern 5b are formed by one electron bean drawing, the relative displacement can be prevented between the groove pattern 5a and the groove pattern 5b.

Note that, in order to prevent the resist film 6a formed in the groove pattern 5b from being oxidized in the mask manufactured in the first embodiment, it is effective to put a pattern forming surface of the mask in an inorganic gas atmosphere such as a nitrogen gas (N2).

Further, a patterning method of forming the resist film 6a only in the groove pattern 5b is not limited to the abovementioned drawing method by the electron beams and, for example, the resist film 6a may be patterned by a ultraviolet ray with a wavelength of 230 nm or more (for example, an i ray (wavelength of 365 nm)).

The gist of the present invention is to provide a practical mask structure of the Cr-less phase shift mask. Accordingly, another wavelength to be an object of the exposure light radiated in using the mask, another material of the resist film 6a, and another material of a mask substrate may be employed. Further, in the first embodiment, the resist film 6a is used as the shade film 6. However, the present invention is not limited to this and may use a material other than the resist film 6a so long as the material has a shade characteristic.

Next, a projection aligner (scanner) used for the mask according to the first embodiment will be explained with reference to the drawings.

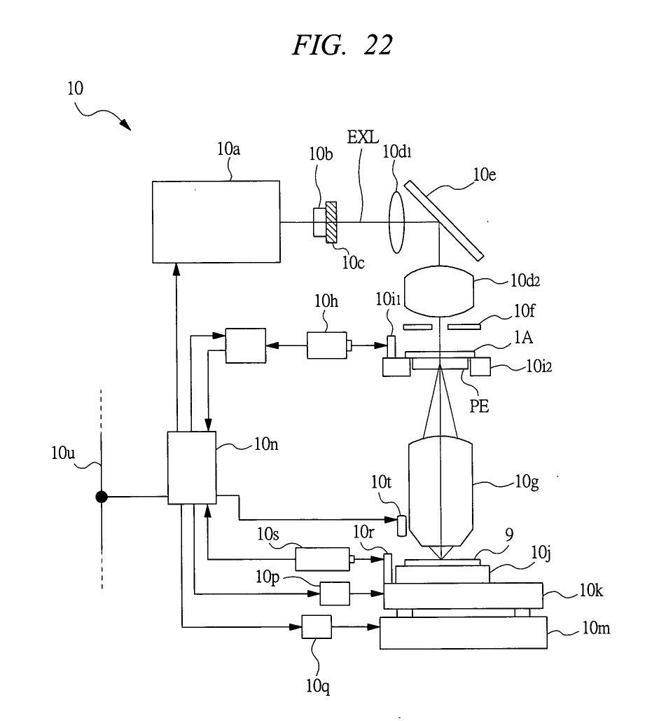

FIG. 22 shows an example of a scanner 10. The scanner 10 is, for example, a scanning type reduction projection aligner with a reduced magnification of 4:1. In FIG. 22, exposure light EXL from an exposure light source 10a radiates a mask (reticle) 1A via a fly eye lens 10b, an aperture 10c, a condenser lenses 10d₁ and 10d₂, and a mirror 10e. Among optical conditions, a coherent factor is adjusted by changing size of an opening portion of an aperture 10f. On the mask 1A, a pericle PE for preventing pattern transfer failures etc. caused due to an attachment of foreign matters is provided. A mask pattern drawn on the mask 1A is projected via a projection lens 10g to a resist film formed on a main surface of a wafer serving as a sample substrate. Note that the mask 1A is disposed on a mask stage 10i₂ controlled by mask position controlling means 10h and a mirror 10i₁, and a center thereof and a light axis of the projection lens 10g are precisely positioned.

A wafer 9 is vacuum-absorbed onto a sample stand 10j. The sample stand 10j is disposed on a movable Z stage 10k in a light-axis direction of the projection lens 10g, namely, in a direction perpendicular to a wafer arrangement surface of the sample stand 10j. Further, the Z stage 10k is disposed on a movable XY stage 10m in a direction parallel with the wafer arrangement surface of the sample stand 10j.

The Z stage 10k and the XY stage 10m are driven respectively by driving units 10p and 10q according to control commands from a main control system 10n, thereby being able to move the wafer 9 to a desired exposure position. The-desired exposure position is precisely monitored by a laser measuring device 10s, as a position of a mirror 10r fixed to the Z stage 10k. Further, a surface position of the wafer 9 is measured by focus position detecting means the normal aligner has. And, by driving the Z stage 10k according to the measurement result, the main surface of the wafer 9 can be made to coincide with an imaging surface of the projection lens 10g.

The mask 1A and the wafer 9 are driven in synchronization according to a reduced magnification. Since an exposure light area scans the main surface of the mask 1A, the mask pattern is scaled down and transferred onto a resist film formed on the main surface of the wafer 9. At this moment, the position of the main surface of the wafer 9 is also dynamically driven and controlled with regard to the scanning of the wafer 9 by the above-mentioned means. In the case where the mask pattern on the mask 1A is overlapped onto a circuit pattern formed on the wafer 9 and is exposed, a position of a mark pattern formed on the wafer 9 is detected by using an alignment detection optical system 10t and the wafer 9 is positioned based on a detection result, whereby the mask pattern is overlapped and transferred onto the mark pattern. Note that the main control system 10n is electrically connected to a network device 10u so that it can remotely monitor conditions of the scanner 10.

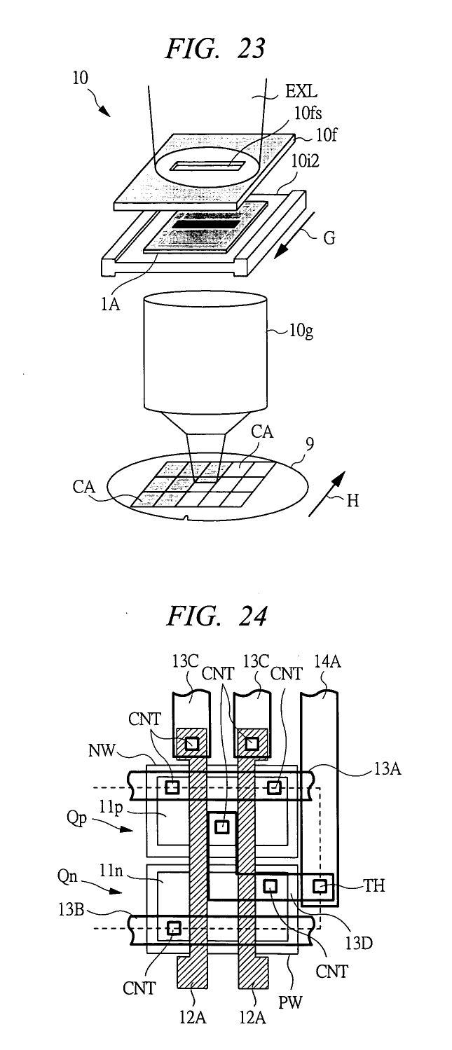

FIG. 23 is a view for schematically explaining a scanning exposure operation of the scanner 10. Note that FIG. 23 is hatched so as to be easily understood.

In a scanning exposure processing utilizing the scanner 10, the respective main surfaces of the mask 1A and the wafer 9 are moved in relatively reversed directions in a state where they are kept in parallel. Namely, the mask 1A and the wafer 9 are in relation of mirror symmetry, so that, during the exposure processing, a scan direction of the mask 1A and that of the wader 9 become reversed like the stage scan directions G and H shown by arrow marks in FIG. 23. Regarding a driving distance, when a reduction ratio is 4:1, displacement of the wafer 9 is 1 if displacement of the mask 1A is 4. At this time, the exposure light EXL is radiated onto the mask 1A via a slit 10fs of a flat rectangular shape in the aperture 10f. Namely, a slit-shaped exposure light area included in the exposure area of the projection lens 10g is used as an effective exposure area.

Though not limited specifically, the width (short-directional dimension) of the slit 10fs is normally, for example, approximately 4 mm to 7 mm on the wafer 9. The slit-shaped exposure light area is continuously moved (scanned) in a width direction (short direction) of the slit 10fs, i.e., in a direction orthogonal or diagonal to a longitudinal direction of the slit 10fs, and further the exposure light is radiated onto the main surface of the wafer 9 via an imaging optics (projection lens 10g). Thereby, the mask pattern of the mask 1A can be transferred to each of a plurality of chip areas CA on the wafer 9. Note that, in this case, although only portions necessary for explaining a function of the scanner 10 are shown, the other portions necessary for the ordinary scanner are the same as those in an ordinary range.

Next, a description will be made of an example of a manufacturing process for a semiconductor device using the mask according to the first embodiment. The manufacturing process of this semiconductor device includes a photolithography step of transferring the pattern of the mask according to the first embodiment onto the wafer by the above-mentioned aligner.

FIG. 24 is a top view showing a portion of a logic element in the semiconductor device. This logic element comprises, for example, two n-channel type MISFETs (Metal Insulator Semiconductor Field Effect Transistors) Qn, and two p-channel type MISFETs Qp. The n-channel MISFET Qn is formed on a p-type well PW formed in the semiconductor substrate and the p-channel type MISFET Qp is formed on an n-channel well NW formed in the semiconductor substrate. The n-channel type MISFET Qn has a gate electrode 12A and an n-type semiconductor area (diffusion layer) 11n formed in a surface area of the p-type well PW, and the p-channel type MISFET Qp has a gate electrode 12A and a p-type semiconductor area (diffusion layer) 11p formed on a surface area of the n-type well NW.

The gate electrode 12A is shared by the n-channel type MISFET Qn and the p-channel type MISFET Qp. The gate electrode 12A is constituted by, for example, a poly side structure in which a silicide film is provided on a top of a simple film of low-resistance poly silicon or a low-resistance poly silicon film, or a poly metal structure in which a barrier film such as a tungsten nitride film is formed on a low-resistance poly silicon film and a metal film such as a tungsten film is formed on this barrier film. A semiconductor substrate portion under the gate electrode 12A becomes a channel area.

A wiring 13A is a power wiring on a high-potential (e.g., approximately 3.3 V or 1.8 V) side, and this power wiring is electrically connected to p-type semiconductor areas 11p of the two p-channel type MISFETs Qp via contact holes CNT. Further, a wiring 13B is a power wiring on, for example, a low-potential (e.g., approximately 0V) side, and this power wiring is electrically connected to an n-type semiconductor areas 11n of the one n-channel type MISFET Qn via the contact hole CNT.

A wiring 13C is an input wiring of a two-input NAND gate circuit, and this input wiring contacts with a wide portion of the gate electrode 12A and is electrically connected thereto via the contact hole CNT. A wiring 13D is electrically connected to both of the n-type semiconductor area 11n and the p-type semiconductor area lip via the contact holes CNT. A wiring 14A is electrically connected to the wiring 13D via a through hole TH.

Next, by using a sectional view taken along the dot line in FIG. 24, a step of forming a logic element in a semiconductor device will be described.

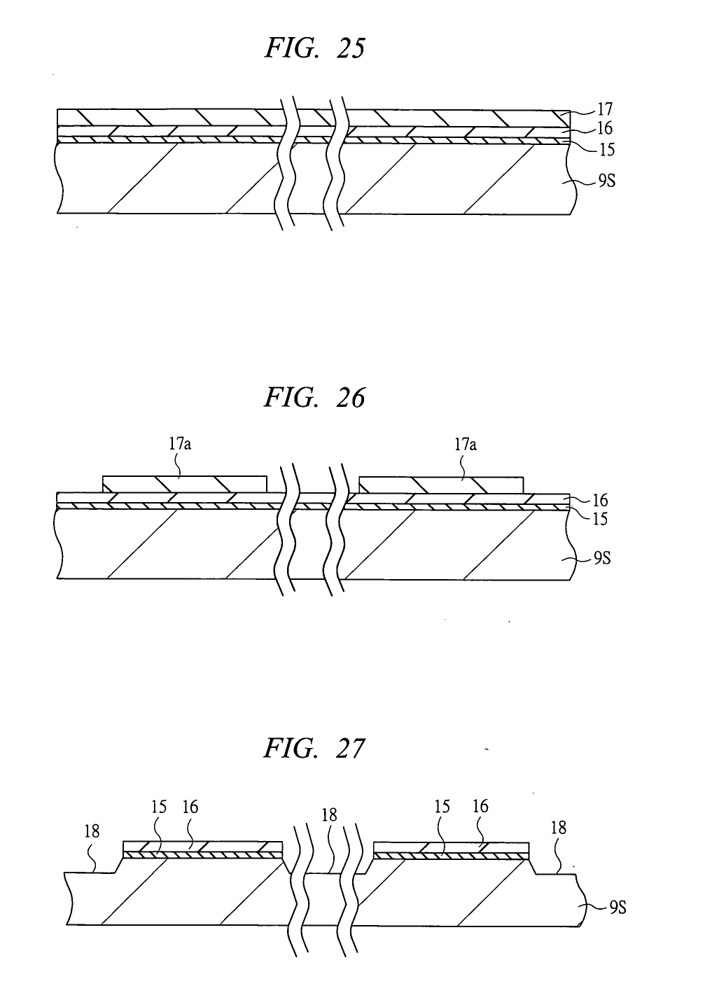

First, as shown in FIG. 25, on a main surface (element formation surface) of a semiconductor substrate 9S made of, for example, p-type silicon monocrystal, an insulating film 15 made of, for example, a silicon oxide film is formed by a thermal oxidation method. Then, on the insulating film 15, an insulating film 16 made of, for example, a silicon nitride film is formed by, for example, a Chemical Vapor Deposition (CVD) method, and a resist film 17 is applied onto this insulating film 16.

Subsequently, by the scanner 10 using a mask in which an element separation groove forming pattern is formed, the exposure processing is performed onto the resist film 17 and thereafter the developing processing is carried out. Thereby, as shown in FIG. 26, the resist film 17 is patterned and a resist pattern 17a is formed on the main surface of the semiconductor substrate 9S. The resist pattern 17a is formed so that the element forming area is exposed and an active area is covered.

Next, as shown in FIG. 27, by using the resist pattern 17a as an etching mask, the exposed insulating film 16 and insulating film 15 are removed sequentially. Thereafter, the semiconductor substrate 9S is further etched and an element separation groove 18 is formed in the semiconductor substrate 9S. Thereafter, the resist pattern 17a is removed.

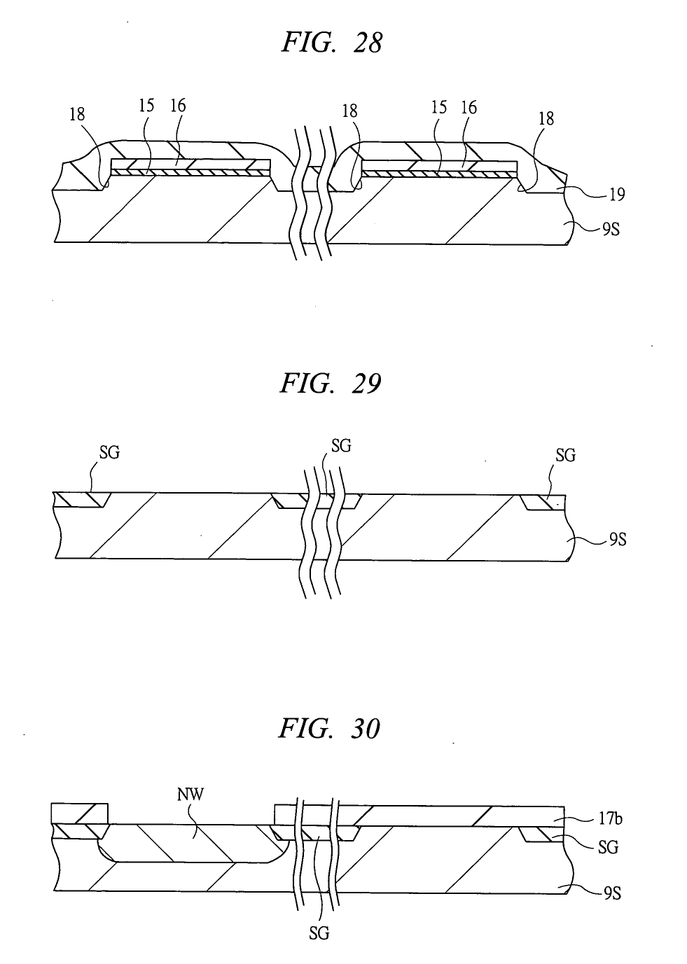

Then, as shown in FIG. 28, on the main surface of the semiconductor substrate 9S, an insulating film 19 made of, for example, a silicon oxide film is formed by a CVD method etc. Thereafter, by using, for example, a Chemical Mechanical Polishing (CMP) method etc., a planarizing processing is carried out to the semiconductor substrate 9S. By this planarizing processing, finally, element separation areas SG as shown in FIG. 29 are formed. In the first embodiment, the element separation area SG is set to have a groove separation structure (trench isolation). However, the present invention is not limited to this and may be formed by, for example, a field insulating film by a Local Oxidization Of Silicon (LOCOS) method.

Next, after a resist film is applied on the main surface of the semiconductor substrate 9S, an exposure processing is performed onto the semiconductor substrate 9S by the scanner 10 utilizing an n-type well forming-mask. Thereby, as shown in FIG. 30, resist patterns 17b are formed on the main surface of the semiconductor substrate 9S. The resist pattern 17b is formed so that the n-type well forming area is exposed and an area other than the n-type well forming area is covered. Thereafter, by using the resist pattern 17b as a mask and by ion-implanting an n-type impurity such as phosphate or arsenic into the semiconductor substrate 9S, the n-type well NW is formed in the n-type well forming area. Then, the resist pattern 17b is removed.

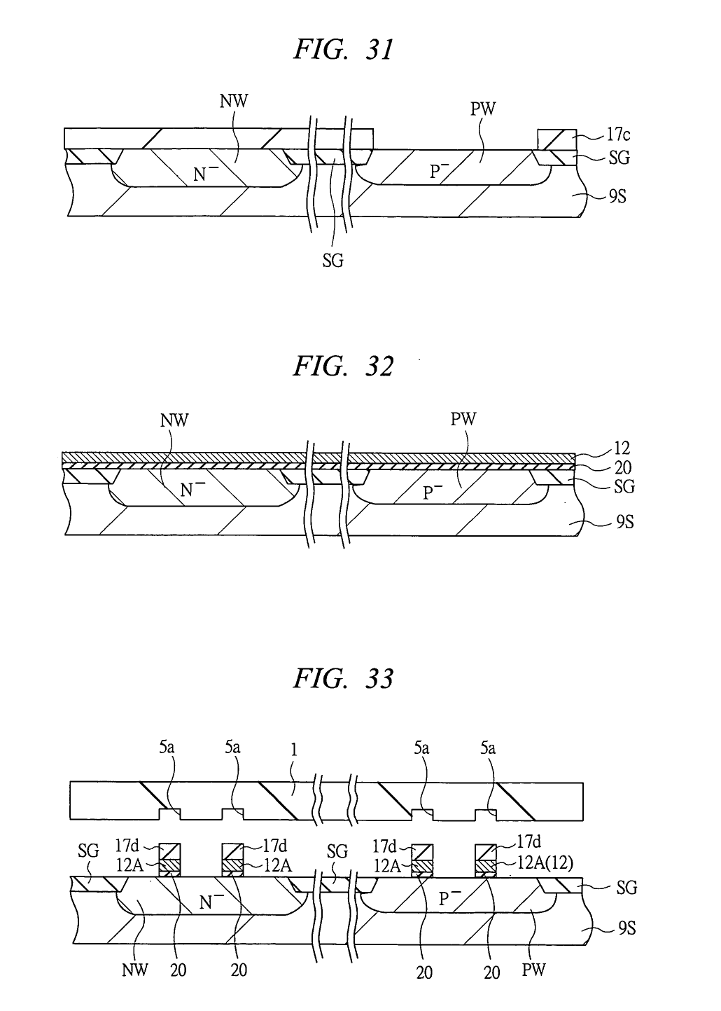

In the same manner, after a resist film is applied onto the main surface of the semiconductor substrate 9S, the exposure processing is performed onto the semiconductor substrate 9S by the scanner 10 utilizing a p-type well forming mask. Thereby, as shown in FIG. 31, a resist patterns 17c are formed on the main surface of the semiconductor substrate 9S. The resist pattern 17c is formed so that the p-type well forming area is exposed and an area other than the p-type well forming area is covered. Thereafter, by using the resist pattern 17c as a mask and by ion-implanting a p-type impurity such as boron into the semiconductor substrate 9S, the p-type well PW is formed in the p-type well forming area. Then, the resist pattern 17c is removed.

Subsequently, as shown in FIG. 32, a gate insulating film 20 made of, for example, a silicon oxide film is formed on the main surface of the semiconductor substrate 9S and further a conductive film 12 made of, for example, a poly silicon film is formed on the gate insulating film 20. The gate insulating film 20 made of a silicon oxide film is formed by, for example, the thermal oxidization method, and the conductive film 12 made of a poly silicon film is formed by, for example, the CVD method.

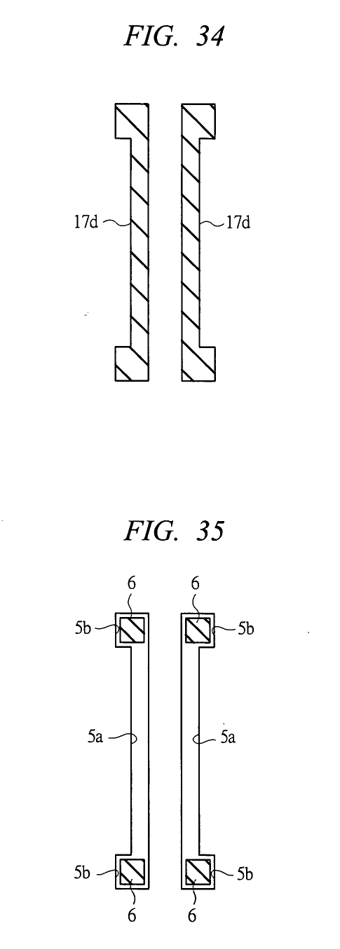

Next, after a resist film (photosensitive film) is applied onto the conductive film 12, the exposure processing is carried out onto the semiconductor substrate 9S by the scanner utilizing the gate electrode forming mask. Thereby, as shown in FIG. 33, on the main surface of the semiconductor substrate 9S, a resist pattern 17d is formed. As shown in FIG. 34 illustrating a planar shape of the resist pattern 17d, the resist pattern 17d is patterned so that the gate electrode forming area is covered with the resist film and an area other than the gate electrode forming area is exposed. Namely, this resist pattern 17d has two line patterns parallel to each other, wherein wide patterns are formed at both ends of each line pattern. Further, the line pattern is relatively narrow while the wide pattern is relatively larger than that of the line pattern. The relatively wide pattern is a pattern for forming a portion connected to a plug of the gate electrode. That is, in an interlayer insulating film to be described later, a contact hole is formed and a portion of this contact hole is formed on the gate electrode (see FIG. 24). Therefore, the plug formed by burying the conductive film in the contact hole and the gate electrode are connected and the portion connected to the plug in the gate electrode pattern becomes a relatively wide pattern.

To form the resist pattern 17d having such a shape, a pattern as shown in FIG. 35 is formed in the mask. Namely, in the mask for forming the gate electrode pattern, line-shaped groove patterns 5a parallel to each other and groove patterns 5b formed at both ends of each groove pattern are formed. In the groove pattern 5b, the shade film 6 shielding the exposure light radiated from the scanner 10 is formed. By using this mask, a line pattern can be formed on the resist film on the semiconductor substrate 9S due to a phase reverse effect caused by the relatively wide groove pattern 5a. Further, also in the relatively wide groove pattern 5b whose shade characteristic is not so preferable at the center, since the shade film 6 is formed therein, the wide pattern with a preferable shade characteristic can be formed on the resist film of the semiconductor substrate 9S.

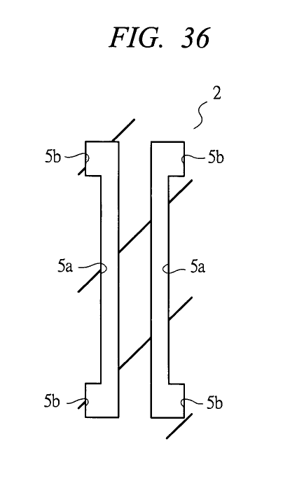

Note that the above-mentioned mask for forming the gate electrode pattern may be formed as shown below. That is, as shown in FIG. 36, after the resist film 2 is formed on the quartz glass substrate, patterning is carried out once by the electron beam drawing (exposure). The patterning is made so that the forming areas of the groove patterns 5a and 5b are opened. Then, by using the patterned resist film 2 as a mask to etching the quartz glass substrate, as shown in FIG. 36, the groove patterns 5a and the groove patterns 5b are formed. At this time, since the respective forming areas of the groove patterns 5a and the groove patterns 5b are formed by carrying out once the electron beam drawing, no relative displacement between the groove patterns 5a and 5b occurs. After the resist film 2 is removed, a new resist film is formed on the quartz glass substrate. Thereafter, by patterning the new resist film using the electron beam drawing, the shade films 6 as shown in FIG. 35 are formed. By doing so, the line-shaped groove patterns 5a parallel to each other and the groove patterns 5b formed at both ends of each groove pattern 5a are formed, and the gate electrode pattern forming mask having the shade films 6 only in the groove patterns 5b can be manufactured. Hereinafter, a description will return to the step of forming the logic element in the semiconductor device.

As shown in FIG. 33, by using the gate electrode pattern forming mask, the resist film on the semiconductor substrate 9S is patterned to form the resist pattern 17d. At this time, in the gate electrode pattern forming mask in FIG. 33, only the groove patterns 5a are shown on the quartz glass substrate 1. This is because that the manufacturing process at the cross section taken along the dot lines in FIG. 24 is shown. Namely, the dot lines in FIG. 24 cuts the relatively narrow line pattern of the gate electrode 12A. Though not illustrated in FIG. 33, the groove patterns 5a as well as the groove pattern 5b, in which the shade film 6 is embedded, are also formed in the gate electrode pattern forming mask.

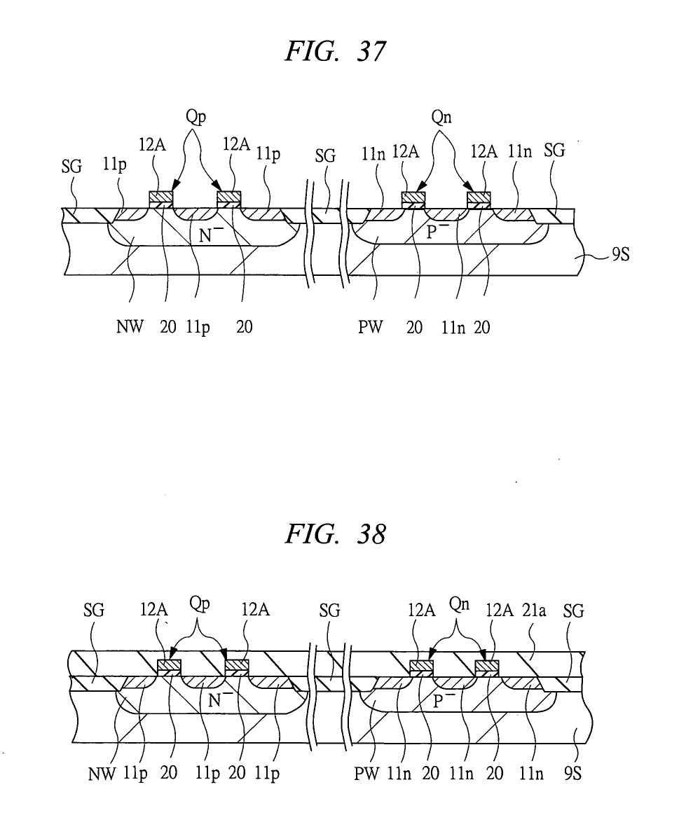

Subsequently, as shown in FIG. 33, by using the resist pattern 17d as a mask to etch the conductive film 12, the gate electrodes 12A are formed. Then, as shown in FIG. 37, an n-type semiconductor area 11n for the n-channel type MISFET Qn and a p-type semiconductor area 11p for the p-channel type MISFET Qp, which function as source and drain areas and wiring layers, are formed. Impurities with high concentrations are introduced into the n-type semiconductor area 11n and the p-type semiconductor area 11p, and are formed in self aligning manners to the gate electrode 12A by, for example, an ion plantation method and a diffusion method.

Next, as shown in FIG. 38, on the main surface of the semiconductor substrate 9S, an interlayer insulating film 21a made of a silicon oxide film on which, for example, phosphor is doped is formed by using, for example, a CVD method. After a resist film is applied onto the interlayer insulating film 21a, the exposure processing is carried out to the semiconductor substrate 9S by the scanner 10 utilizing a contact hole forming mask. Thereby, as shown in FIG. 39, resist patterns 17e are formed over the main surface of the semiconductor substrate 9S. The resist pattern 17e is formed so that a roughly circular contact hole forming area is exposed and an area other than the contact hole forming area is covered. By using the resist pattern 17e as a mask, contact holes CNT are formed in the interlayer insulating film 21a.

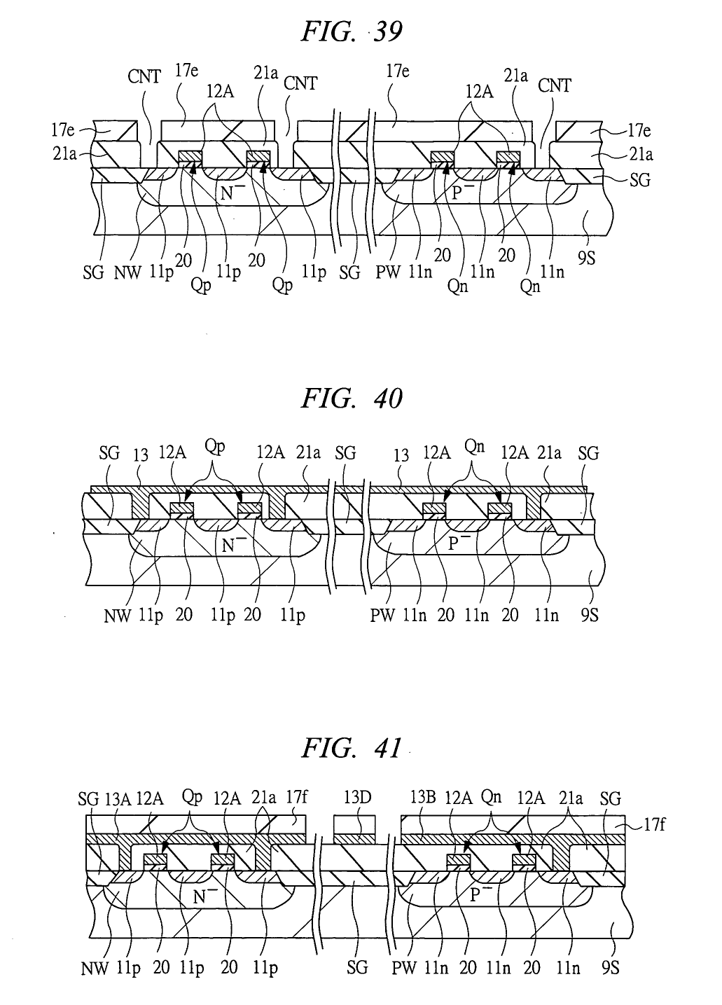

Subsequently, as shown in FIG. 40, after the resist pattern 17e is removed, a conductive film 13 made of, for example, an aluminum film, aluminum alloy film, or copper film is formed on the semiconductor substrate 9S by the spattering method. Then, after a resist film is applied onto the conductive film 13, the exposure processing is carried out to the semiconductor substrate 9S by the scanner 10 utilizing a wiring forming mask. Thereby, as shown in FIG. 41, resist patterns 17f are formed over the main surface of the semiconductor substrate 9S. The resist pattern 17f is formed so that the wiring forming area is covered and an area other than the wiring forming area is exposed. Thereafter, by using the resist patterns 17f as a mask to etch the conductive film 13, wirings 13A to 13D are formed.

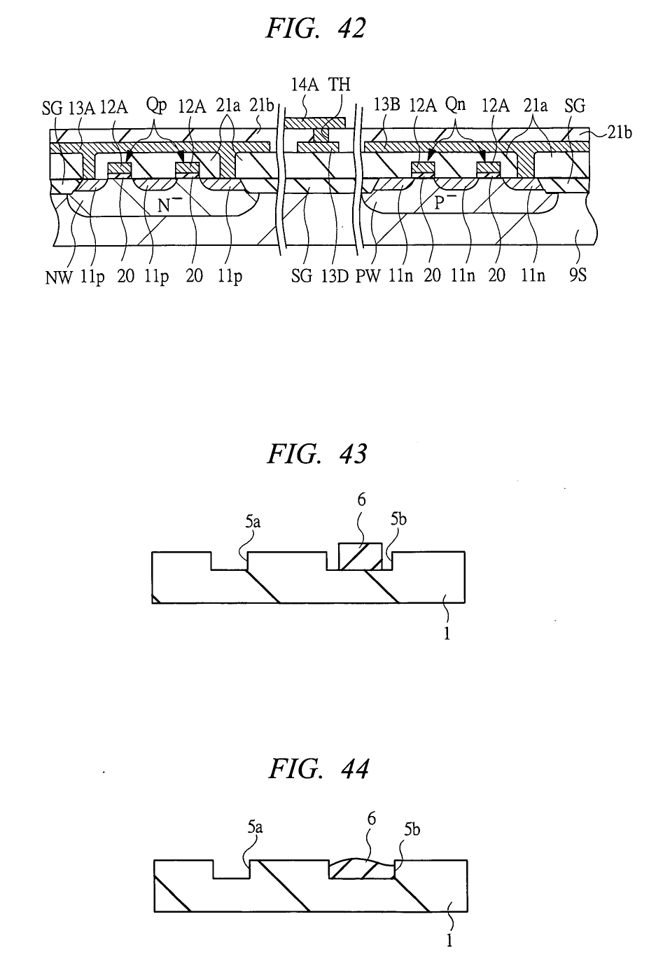

Thereafter, as shown in FIG. 42, an interlayer insulating film 21b is formed over the main surface of the semiconductor substrate 9S by, for example, the CVD method and a through hole TH and an upper-layer wiring 14A are formed sequentially, whereby the logic elements in the semiconductor device can be formed.

According to the first embodiment, a Cr-less phase shift mask formed by the groove pattern 5a and the groove pattern 5b in which the shade film made of, for example, a resist film is embedded is used as a gate electrode forming mask, whereby a cost of the mask is reduced. Namely, since the mask according to the first embodiment can be formed in the simplified process, a mask price is reduced. Especially, the mask according to the first embodiment is suitable for a small amount of various kinds of semiconductor devices that requires reducing the mask price.

### Second Embodiment

In a second embodiment, a modified example of the first embodiment will be described. FIG. 43 is a sectional view showing the mask according to the first embodiment. Namely, in FIG. 43, the relatively narrow groove pattern 5a and the groove pattern 5b wider than the groove pattern 5a are formed in the quartz glass substrate 1. Further, the shade film 6 made of, for example, a resist film is formed in the groove pattern 5b. At this time, since the shade film 6 is formed in positional engagement with the groove pattern 5b, it has an engagement allowance. Accordingly, the width of the shade film 6 is smaller than that of the groove pattern 5b.

In the second embodiment, after a mask having the same structure as that shown in FIG. 43 is formed, as shown in FIG. 44, a heat processing is carried out at such a temperature that the shade film 6 formed in the groove pattern 5b starts flowing, i.e., at a temperature equal to or higher than the temperature at which the shade film 6 gets soft. As a result, as shown in FIG. 44, the shade film 6 flows and is embedded in the groove pattern 5b without any gap. Therefore, in the second embodiment, the mask, which fully fills the groove pattern 5b with the shade film 6, can be formed.

Thereby, the influence of displacement of the shade film 6 with respect to the groove pattern 5b can be removed, and the mask can be formed with high precision. Further, because a side wall (side surface) of the shade film 6 contacts with the quartz glass substrate 1, oxygen is hardly supplied to a side surface of the shade film 6. Accordingly, when an ultraviolet ray serving as exposure light is radiated onto the mask, a reaction of the shade film 6 and oxygen is suppressed and consequently fluctuations in mask dimensions during use of the mask can be suppressed.

As described above, the invention made by the present inventors has been specifically described based on the embodiments. However, needless to say, the present invention is not limited to the above embodiments and may be variously altered and modified without departing from the gist thereof.

In the first embodiment, an example of using the normal aligner has been explained. However, the mask according to the first embodiment may also be used in an aligner employing, for example, a liquid immersion exposure technique. Generally, the resolution of the aligner is in proportion with the wavelength of illumination light and in reverse proportion with the number of apertures of lens. Meanwhile, the number of apertures of lens is in proportion with a refraction factor of a medium n through which the exposure light passes. Normally, the medium, through which exposure light passes, is air and therefore n=1. However, in the liquid immersion exposure technique, the medium, through which the exposure light passes, is pure water and therefore n=1.44 (when the light source is an ArF excimer laser). Accordingly, if the mask according to the first embodiment is used in a liquid immersion aligner, the resolution can be further improved in comparison with the case of using the normal aligner.

The present invention may be used widely in a manufacturing field of semiconductor devices.

1. A method of manufacturing a semiconductor device, comprising the step of:
exposing a predetermined pattern onto a photosensitive film formed over a semiconductor substrate by using a photo mask,
wherein said photo mask includes:
(a) a plurality of groove patterns formed over a blank; and
(b) a shade film formed in each of several ones among said plurality of groove patterns.

2. The method of manufacturing a semiconductor device according to claim 1,
wherein said plurality of groove patterns include a first groove pattern with a first width and a second groove pattern with a second width larger than said first width, and
said shade film is formed in said second groove pattern.

3. The method of manufacturing a semiconductor device according to claim 1,
wherein said shade film is formed of an organic photosensitive resin film.

4. The method of manufacturing a semiconductor device according to claim 1,
wherein said shade film is formed of a resist film sensitive to an electron beam.

5. The method of manufacturing a semiconductor device according to claim 2,
wherein a width of said shade film is narrower than that of said second groove pattern.

6. The method of manufacturing a semiconductor device according to claim 1,
wherein a gate electrode pattern for electric field effect transistor is formed in said photo mask.

7. The method of manufacturing a semiconductor device according to claim 6,
wherein said gate electrode pattern includes a first groove pattern with a first width and a second groove pattern whose width is larger than said first width and in which a shade film is formed, and
said second groove pattern is a pattern for forming a portion connected to a plug in a gate electrode.

8. A method of manufacturing a semiconductor device, comprising the step of:
exposing a predetermined pattern onto a photosensitive film formed over a semiconductor substrate by using a photo mask,
wherein said photo mask is formed through the steps of:
(a) forming a first resist film over a blank;
(b) patterning said first resist film;
(c) using said patterned first resist film as a mask to form a plurality of groove patterns different in width in said blank;
(d) removing said patterned first resist film;
(e) forming a second resist film over said blank after said step (d); and
(f) performing patterning so that said second resist film is left only in the relatively wide groove pattern among said plurality of groove patterns different in width, which are formed in said blank.

9. The method of manufacturing a semiconductor device according to claim 8,
wherein said step (c) forms a first groove pattern with a first width and a second groove pattern whose width is larger than said first width in said blank, and
said step (f) forms said second resist film only in said second groove pattern.

10. The method of manufacturing a semiconductor device according to claim 9,
wherein said step (f) forms said second resist film whose width is narrower than that of said second groove pattern in said second groove pattern, and
said photo mask is formed further through the step of:
(g) performing a heat processing to said photo mask at a temperature equal to or higher than that at which said second resist film gets soft, after said step (f).

11. The method of manufacturing a semiconductor device according to claim 8,
wherein said second resist film is a negative type resist film.

12. The method of manufacturing a semiconductor device according to claim 8,
wherein said step (b) patterns said first resist film by using an electron beam, and
said step (f) patterns said second resist film by using the electron beam.

13. The method of manufacturing a semiconductor device according to claim 12,
wherein said step (a) forms a first conductive film over said first resist film, and
said step (e) forms a second conductive film over said second resist film.

14. The method of manufacturing a semiconductor device according to claim 13,
wherein said first and second conductive films are formed of water soluble organic films.

15. The method of manufacturing a semiconductor device according to claim 14,
wherein said step (b) performs a developing processing to the first resist film and removes said first conductive film by the developing processing, and
said step (f) performs the developing processing to said second resist film and removes said second conductive film by the developing processing.

16. The method of manufacturing a semiconductor device according to claim 8,
wherein said step (f) uses an ultraviolet ray with a wavelength of 230 nm or more to pattern said second resist film.

17. The method of manufacturing a semiconductor device according to claim 16,
wherein said step (f) uses an i ray with a wavelength of 365 nm to pattern said second resist film.

18. The method of manufacturing a semiconductor device according to claim 8,
wherein a light absorbing or shielding agent is added to said second resist film.

19. The method of manufacturing a semiconductor device according to claim 8, wherein said photo mask is formed further through the step of:
(g) performing a hardening processing for improving a durability of said second resist film with respect to exposure light irradiation during use of said photo mask after said step (f).

20. The method of manufacturing a semiconductor device according to claim 19,
wherein said step (g) performs a heat processing or irradiates an ultraviolet ray instead of said hardening processing.
